(19) United States
(12) Patent Application Publication
(10) Pub. No.: US 2010/0086791 A1
(43) Pub. Date: Apr. 8, 2010

(54) Optical film and coating method thereof

(75) Inventor: Hsin-Chin Hung, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI Precision Industry CO., LTD., Tu-Cheng City (TW)

(21) Appl. No.: 12/587,583

(22) Filed: Oct. 8, 2009

(30) Foreign Application Priority Data
Oct. 8, 2008 (CN) 200810304770.X

(51) Int. Cl. B32B 15/00; C23C 14/34

(52) U.S. Cl. 428/457; 204/192.13

(57) ABSTRACT

An exemplary optical film includes a transparent substrate having a surface, and an optical film coated on the surface of the transparent substrate. The optical film includes pure metal ions and reaction compounds mixed with the pure ions. The proportion of the ions to the reaction compounds in the optical film gradually changes along a direction from the surface of the transparent substrate to a surface of the optical film farthest from the surface of the transparent substrate. An exemplary method to form such an optical film is also provided.

### BACKGROUND

1. Technical Field

The disclosure relates to an optical film that is used in optical elements, and to a method of coating the optical film on an object such as a substrate.

2. Description of Related Art

Optical films are widely used in optical elements to modify or affect the paths of light beams incident thereon. Optical films are commonly formed by a physical vapor deposition (PVD) method. For example, PVD is used to deposit thin films of a material onto a surface of an article, by the condensation of a vaporized form of the material. For achieving different optical and/or mechanical characteristics, optical films are typically multilayer structures. A multilayer structure usually has different layers alternately stacked one on the other. The different layers have related compositions, but still have different indices of refraction corresponding to various wavelengths of interest. Typically, the multilayer structures of different optical films are formed in different PVD equipment, under different conditions such as at different temperatures, time durations, voltages and so on, and using different materials. Therefore the manufacture of different optical films is complicated and costly.

Thus what is needed is an optical film and a method of coating an optical film, in which the above-described problems are eliminated or at least alleviated.

### BRIEF DESCRIPTION OF THE DRAWINGS

FIG. 1 is a flow diagram of a coating method for forming an optical film according to a first exemplary embodiment.

FIG. 2 is a chart of a vaporizing rate of a target metal versus time, together with a related chart of a releasing rate of reaction gas versus time, according to the method shown in FIG. 1.

FIG. 3 is a flow diagram of a coating method for forming an optical film according to a second exemplary embodiment.

FIG. 4 is a chart of a vaporizing rate of a target metal versus time, together with a related chart of a releasing rate of reaction gas versus time, according to the method shown in FIG. 3.

FIG. 5 is a flow diagram of a coating method for forming an optical film according to a third exemplary embodiment.

FIG. 6 is a chart of a vaporizing rate of a target metal versus time, together with a related chart of a releasing rate of reaction gas versus time, according to the method shown in FIG. 5.

FIG. 7 is a flow diagram of a coating method for forming an optical film according to a fourth exemplary embodiment.

FIG. 8 is a chart of a vaporizing rate of a target metal versus time, together with a related chart of a releasing rate of reaction gas versus time, according to the method shown in FIG. 7.

FIG. 9 is a side plan view of a transparent substrate with an optical film formed thereon according to any one of the methods shown in FIGS. 1, 3, 5, and 7, the transparent substrate with optical film constituting an optical element.

FIG. 10 is a graph showing spectral transmittance and spectral reflectance characteristics versus wavelength, for the optical element of FIG. 9.

### DETAILED DESCRIPTION

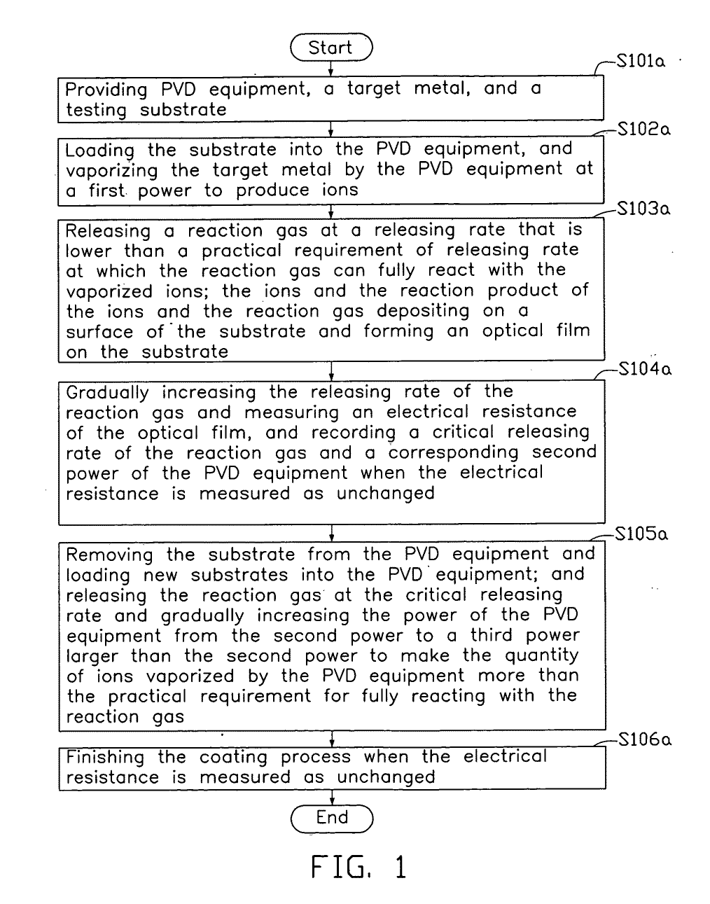

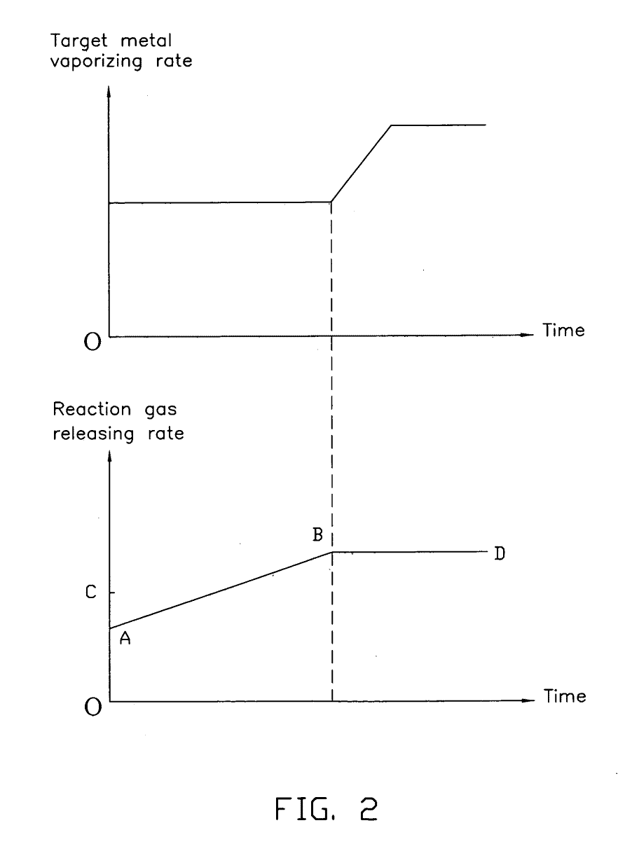

FIGS. 1 and 2 relate to a coating method for forming an optical film according to a first exemplary embodiment. The coating method includes steps as follows:

First of all, in step S101a, PVD equipment, a target metal and a testing substrate are provided. The PVD equipment includes a reaction chamber, and a cathode ray gun and a gas injector both arranged in the reaction chamber. The target metal and the testing substrate are arranged in the reaction chamber of the PVD equipment for a preparatory calibrating process implemented before a coating process (see below). The cathode ray gun provides a high energy source such as a beam of electrons or ions to bombard and vaporize a surface of the target metal and thereby produce ions of the target metal. The gas injector communicates with a gas feed valve via a gas feed line for supplying an appropriate reaction gas which can react with the ions vaporized from the target metal to produce a number of reaction products to be coated on the testing substrate. In the present embodiment, the target metal to be coated on the testing substrate is selected from any of various reflective materials which can reflect light well. The reaction products, produced from the reaction of the reaction gas and the target metal, serve as a light absorber to appropriately absorb light. Exemplarily, the target metal is chromium (Cr) or titanium (Ti). The testing substrate is a transparent sheet of glass, and is used in the calibrating process as a reference for operators to measure and obtain a series of proper reference parameters employed in the coating method. The calibrating process is performed in steps S102a to S104a, described below.

The calibrating process includes firstly, in step S102a, loading the target metal and the testing substrate into the reaction chamber of the PVD equipment. Then the cathode ray gun is operated at a first power to bombard the target metal. Exemplarily, before being placed into the reaction chamber, the testing substrate should be cleaned to remove any contaminants on its surface. When bombarded by the cathode ray gun, the surface of the target metal is vaporized to produce a great amount of ions filling the reaction chamber.

In step S103a, the gas injector releases reaction gas at a first releasing rate A, which typically is measured in standard-state cubic centimeters per minute (sccm). The first releasing rate A (sccm) is lower than a practical requirement of a releasing rate at which the reaction gas released by the gas injector can fully react with the ions vaporized from the target metal by the cathode ray gun operating at the first power. In detail, a vaporizing rate of the target metal can be read from the PVD equipment, and a theoretical value C (sccm) of the releasing rate of the reaction gas can be directly calculated accordingly. The actual vaporizing rate depends on characteristics (such as melting point) of the target metal and the power of the cathode ray gun of the PVD equipment. In the present embodiment, the actual vaporizing rate depends on the characteristics of Cr or Ti, including the melting point of Cr or Ti, and importantly depends on the power of the cathode ray gun of the PVD equipment. In the present embodiment, a reference power of the cathode ray gun of the PVD equipment is proper at approximately 1000 watts (W). At the theoretical value C (sccm) of the releasing rate, the reaction gas released by the gas injector can theoretically fully react with the ions vaporized from the target metal. The theoretical value C (sccm) serves as a reference standard for setting up the first releasing rate A (sccm) of the reaction gas. In the present embodiment, the first releasing rate A (sccm) is lower than the theoretical value C (sccm). The difference between the theoretical value C (sccm) and the first releasing rate A (sccm) can be of a proportion indicated in FIG. 2, as if the chart therein of releasing rate of reaction gas versus time were drawn to scale. In the present embodiment, the reaction gas released by the gas injector is oxygen or nitrogen, and correspondingly the reaction products produced during the reaction of the reaction gas and the target metal are titanium oxides, chromium oxides, titanium nitrides, or chromium nitrides. During the coating process, a portion of vaporized ions is reacted with the reaction gas, and the residual vaporized ions as well as the reaction products are deposited on the surface of the testing substrate to form an optical film.

In step S104a, the releasing rate of the reaction gas is gradually increased, and simultaneously an electrical resistance of a surface of the optical film is repeatedly measured. During the depositing of the vaporized ions and the reaction products, the electrical resistance of the surface of the optical film changes, according to the varying proportions of the pure ions of the target metal and the reaction products present on the surface at any one time. Generally, the more reaction products contained in the optical film, the higher the electrical resistance of the surface of the optical film. If the vaporized ions have been fully reacted with the reaction gas, the surface of the optical film becomes completely covered by the reaction products. As a result, the electrical resistance of the surface of the optical film remains at a constant or invariant value. In other words, when the electrical resistance of the surface of the optical film reaches and maintains a constant or invariant value, it means the vaporized ions of the target metal have been fully reacted with the reaction gas. This value is defined as a critical releasing rate B (sccm) of the reaction gas, and is recorded as a reference parameter. In the present embodiment, the critical releasing rate B (sccm) is larger than between the theoretical value C (sccm). The difference between the critical releasing rate B (sccm) and the first releasing rate A (sccm) can be of a proportion indicated in FIG. 2, as if the chart therein of releasing rate of reaction gas versus time were drawn to scale. The time needed for the electrical resistance of the surface of the optical film to reach the constant or invariant value is, for example, of the order of 1 hour. Understandably, the optical parameters of the optical film can vary according to different requirements, and can be achieved by increasing the releasing rate of the reaction gas to change the composition of the optical film.

After the calibrating process, the reference parameter B (sccm) has been obtained, and the testing substrate is removed from the reaction chamber of the PVD equipment. In step S105a, a plurality of new and clean substrates are then loaded into the reaction chamber of the PVD equipment. Such substrates can for example be transparent sheets of glass. To form an optical film on each of the substrates includes operating the gas injector to release reaction gas at a releasing rate D (sccm) identical to the reference parameter B (sccm) together with gradually increasing the power of the cathode ray gun from the first power to a second power higher than the first power. Thereby, the vaporizing rate of the target metal at the second power is larger than the practical requirement for fully reacting the vaporized ions of the target metal with the reaction gas released at the releasing rate B (sccm). In this way, an optical film is gradually built on a bare surface of each of the substrates.

When the cathode ray gun stably operates at the second power, the vaporizing quantity of the target metal and the releasing quantity of the reaction gas remain stable and unchanged. Therefore the proportion of the vaporized ions of the target metal to the reaction products is constant. Accordingly, in step S106a, when the electrical resistance of each optical film remains at a constant or invariant value, the coating process is finished and the optical films are produced. In each optical film, a density of the ions of the target metal gradually increases along a direction from the bare surface of the substrate to the exposed surface of the optical film.

In one more particular example, with the, cathode ray gun stably operating at the second power and the vaporizing quantity of the target metal and the releasing quantity of the reaction gas remaining stable and unchanged, the reaction gas can be released at a rate of approximately 10 sccm when the reaction gas is oxygen. At this time, the pressure of the reaction chamber of the PVD equipment can be approximately 4×10⁻³ torr, and the substrates may be heated at a temperature of approximately 200° C. In another more particular example, with the cathode ray gun stably operating at the second power and the vaporizing quantity of the target metal and the releasing quantity of the reaction gas remaining stable and unchanged, the reaction gas can be released at a rate of approximately 200 sccm when the reaction gas is nitrogen. At this time, the pressure of the reaction chamber of the PVD equipment can be approximately 4×10⁻³ torr, and the substrates may be unheated.

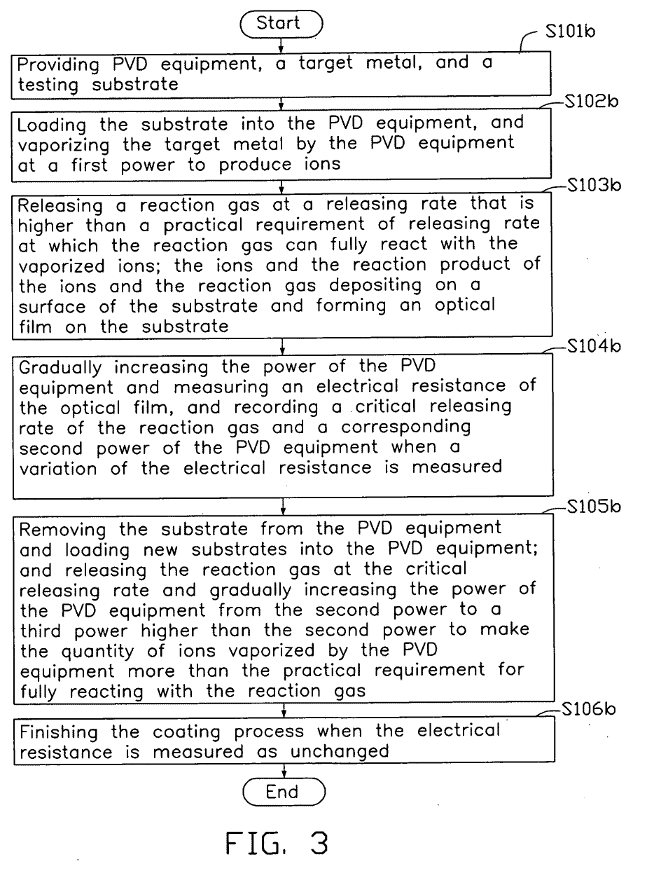

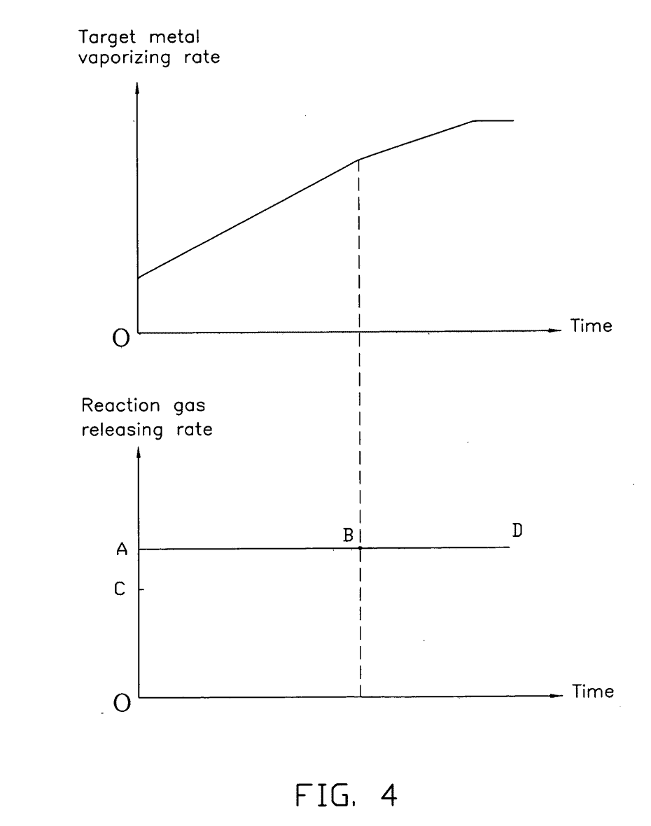

FIGS. 3 and 4 relate to a coating method for forming an optical film according to a second exemplary embodiment. The coating method is similar to that of the first exemplary embodiment, and includes steps as follows. The first and second steps S101b and S102b of the second exemplary embodiment are similar to steps S101a and S102a of the first exemplary embodiment. Accordingly, a description of steps S101b and S102b is omitted, for the sake of brevity.

In step S103b, the gas injector releases reaction gas at a first releasing rate A (sccm), which is higher than a practical requirement of a releasing rate at which the reaction gas released by the gas injector can fully react with the ions vaporized from the target metal by the cathode ray gun operating at the first power. In detail, a vaporizing rate of the target metal can be read from the PVD equipment, and a theoretical value C (sccm) of the releasing rate of the reaction gas is directly calculated accordingly. The actual vaporizing rate depends on characteristics (such as melting point) of the target metal and the power of the cathode ray gun of the PVD equipment. In the present embodiment, the actual vaporizing rate depends on characteristics of Cr or Ti, including the melting point of Cr or Ti, and importantly depends on the power of the cathode ray gun of the PVD equipment. In the present embodiment, the reference power of the cathode ray gun of the PVD is proper at approximately 1000 W. At the theoretical value C (sccm) of the releasing rate, the reaction gas released by the gas injector can theoretically fully react with the vaporized ions of the target metal. The theoretical value C (sccm) serves as a reference standard for setting up the first releasing rate of the reaction gas. In the present embodiment, the first releasing rate A (sccm) is higher than the theoretical value C (sccm). The difference between the first releasing rate A (sccm) and the theoretical value C (sccm) can be of a proportion indicated in FIG. 4 as if the chart therein of releasing rate of reaction gas versus time were drawn to scale. In the present embodiment, the reaction gas released by the gas injector is oxygen or nitrogen, and correspondingly the reaction products produced during the reaction of the reaction gas and the target metal are titanium oxides, chromium oxides, titanium nitrides, or chromium nitrides. During the coating process, all of the vaporized ions are reacted with the reaction gas and deposited on the surface of the testing substrate to form an optical film.

In step S104b, the power of the cathode ray gun of the PVD equipment is gradually increased, and simultaneously an electrical resistance of the surface of the optical film is repeatedly measured. In this process, the vaporized ions can fully react with the reaction gas because the quantity of the reaction gas is more than the practical requirement for fully reacting with the vaporized ions. Therefore, the electrical resistance of the surface of the optical film reaches a threshold and remains unchanged before the residual reaction gas has been consumed by the vaporized ions of the target metal. With the increasing of the power of the cathode ray gun, the quantity of the vaporized ions increases correspondingly, and therefore, the residual reaction gas can be consumed by the increased amount of vaporized ions produced. When the quantity of the vaporized ions exceeds the practical requirement for fully reacting with the reaction gas, a portion of the vaporized ions is deposited on the optical film along with the depositing of reaction products of the reaction gas and the vaporized ions. As a result, the electrical resistance of the surface of the optical film changes. Accordingly, when a variation of the electrical resistance of the surface of the optical film is measured, it means that the vaporized ions and the reaction gas are not completely reacted. A second power of the cathode ray gun that is supplied at the time of the variation of the electrical resistance is correspondingly recorded as a reference parameter. In this embodiment, the gas injector releases the reaction gas at a releasing rate B (sccm) equal to the first releasing rate A (sccm) throughout the calibrating process. The time needed for the electrical resistance of the surface of the optical film to reach the constant or invariant value is, for example, of the order of 1 hour. Understandably, the optical parameters of the optical film can vary according to different requirements, and can be achieved by increasing the power of the cathode ray gun to change the composition of the optical film.

After the calibrating process, the reference parameter of the second power of the cathode ray gun has been obtained, and the testing substrate is removed from the reaction chamber of the PVD equipment. In step S105b, a plurality of new and clean substrates are then loaded into the reaction chamber of the PVD equipment. To form an optical film on each of the substrates includes operating the gas injector to release reaction gas at a releasing rate D (sccm) equal to the first releasing rate A (sccm), together with gradually increasing the power of the cathode ray gun from the second power to a third power higher than the second power. Thereby, the vaporizing rate of the target metal at the third power is higher than the practical requirement for fully reacting the vaporized ions of the target metal with the reaction gas released at the releasing rate B (sccm). In this way, an optical film is gradually built on a bare surface of each of the substrates.

When the cathode ray gun stably operates at the third power, the vaporizing quantity of the target metal and the releasing quantity of the reaction gas remain unchanged. Therefore the proportion of the vaporized ions of the target metal to the reaction products is constant. Accordingly, in step S106b, when the electrical resistance of the surface of each optical film remains at a constant or invariant value, the coating process is finished and the optical films are produced. In each optical film, a density of the ions of the target metal gradually increases along a direction from the bare surface of the substrate to the exposed surface of the optical film.

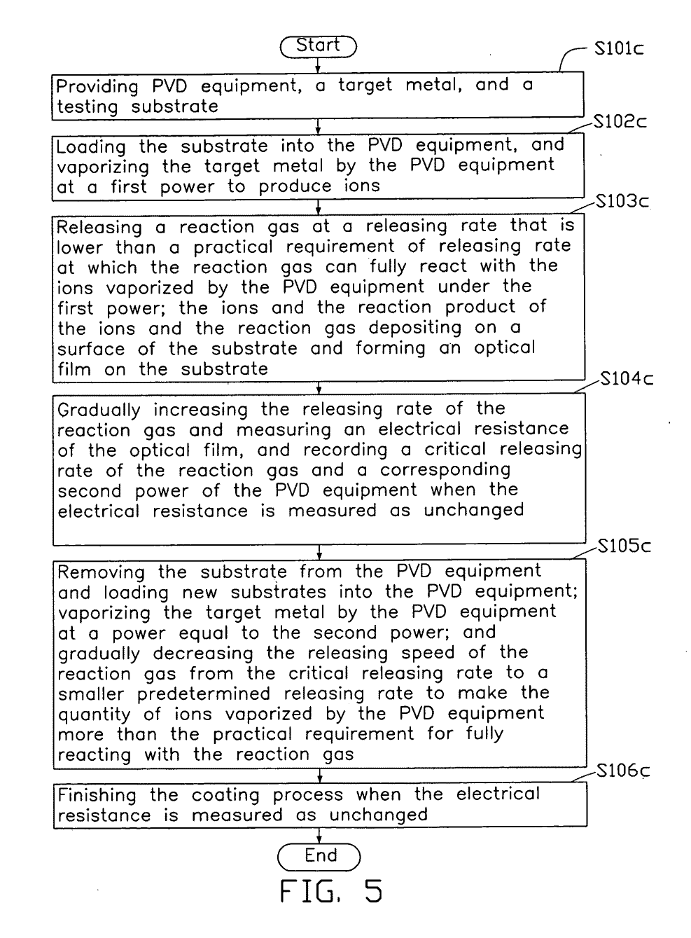

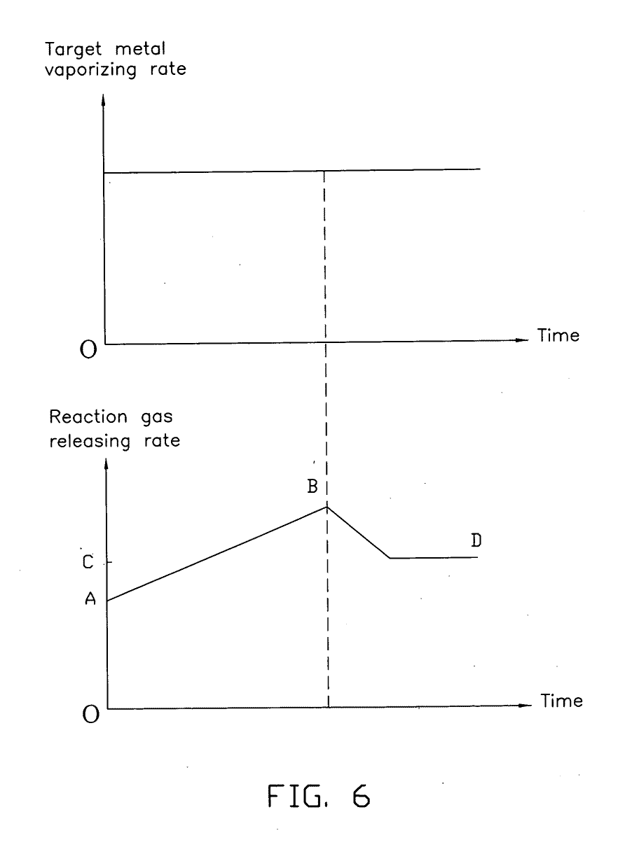

FIGS. 5 and 6 relate to a coating method of a third exemplary embodiment. The coating method is similar to that of the first exemplary embodiment, and includes steps as follows. The first and second steps S101c and S102c of the third exemplary embodiment are similar to steps S101a and S102a of the first exemplary embodiment. Accordingly, a description of steps S101c and S102c is omitted, for the sake of brevity.

In step S103c, the gas injector releases reaction gas at a first releasing rate A (sccm) that is lower than a practical requirement of a releasing rate at which the reaction gas released by the gas injector can fully react with the ions vaporized from the target metal by the cathode ray gun operating at the first power. In detail, a vaporizing rate of the target metal can be read from the PVD equipment, and a theoretical value C (sccm) of the releasing rate of the reaction gas is directly calculated accordingly. The actual vaporizing rate depends on characteristics (such as melting point) of the target metal and the power of the cathode ray gun of the PVD equipment. In the present embodiment, the actual vaporizing rate depends on characteristics of Cr or Ti, including the melting point of Cr or Ti, and importantly depends on the power of the cathode ray gun of the PVD equipment. In the present embodiment, the reference power of the cathode ray gun of the PVD is proper at approximately 1000 W. At the theoretical value C (sccm) of the releasing rate, the reaction gas released by the gas injector can theoretically fully react with the ions of the target metal vaporized by the cathode ray gun at the first power. The theoretical value C (sccm) serves as a reference standard for setting up or adjusting the first releasing rate A (sccm). In the present embodiment, the first releasing rate A (sccm) is lower than the theoretical value C (sccm). The difference between the theoretical value C (sccm) and the first releasing rate A (sccm) can be of a proportion indicated in FIG. 6 as if the chart therein of releasing rate of reaction gas versus time were drawn to scale. In the present embodiment, the reaction gas released by the gas injector is oxygen or nitrogen, and correspondingly the reaction products produced during the reaction of the reaction gas and the target metal are titanium oxides, chromium oxides, titanium nitrides, or chromium nitrides. During the coating process, a portion of the vaporized ions is reacted with the reaction gas, and the residual vaporized ions as well as the reaction products are deposited on the surface of the testing substrate to form an optical film.

In step S104c, the releasing rate of the reaction gas is gradually increased, and simultaneously an electrical resistance of the surface of the optical film is repeatedly measured. During the depositing of the vaporized ions and the reaction products, the electrical resistance of the surface of the optical film changes, according to the varying proportions of the pure ions of the target metal and the reaction products present on the surface at any one time. Generally, the more reaction products contained in the optical film, the higher the electrical resistance of the surface of the optical film. If the vaporized ions have been fully reacted with the reaction gas, the surface of the optical film becomes completely covered by the reaction products. As a result, the electrical resistance of the surface of the optical film remains at a constant or invariant value. In other words, when the electrical resistance of the surface of the optical film reaches and maintains a constant or invariant value, it means that the vaporized ions of the target metal have been fully reacted with the reaction gas. This value is defined as a critical releasing rate B (sccm) of the reaction gas, and is recorded as a reference parameter. In this embodiment, the cathode ray gun operates at the first power throughout the calibrating process. In the present embodiment, the critical releasing rate B (sccm) is larger than the theoretical value C (sccm). The difference between the critical releasing rate B (sccm) and the first releasing rate A (sccm) can be of a proportion indicated in FIG. 6, as if the chart therein of releasing rate of reaction gas versus time were drawn to scale. The time needed for the electrical resistance of the surface of the optical film to reach the constant or invariant value is, for example, of the order of 1 hour. Understandably, the optical parameters of the optical film can vary according to different requirements, and can be achieved by increasing the releasing rate of the reaction gas to change the composition of the optical film.

After the calibrating process, the reference parameter of the releasing rate B (sccm) of the reaction gas has been obtained, and the testing substrate is removed from the reaction chamber of the PVD equipment. In step S105c, a plurality of new and clean substrates are then loaded into the reaction chamber of the PVD equipment. To form an optical film on each of the substrates includes operating the gas injector to release reaction gas at a releasing rate that gradually changes from the releasing rate B (sccm) to a releasing rate D (sccm) lower than the releasing rate B (sccm), while operating the cathode ray gun at the first power during this time. Thereby, the vaporizing rate of the target metal at the second power that is equal to the first power is higher than the practical requirement for fully reacting the vaporized ions of the target metal with the reaction gas released by the gas injector at a releasing rate that is lower than the releasing rate B (sccm). In this way, an optical film is gradually built on a bare surface of each of the substrates.

In the present embodiment, the releasing rate D (sccm) is approximately the same as the theoretical value C (sccm). When the reaction gas is released by the gas injector at the stable releasing rate of D (sccm), the vaporizing quantity of the target metal and the releasing quantity of the reaction gas remain unchanged. Therefore the proportion of the vaporized ions of the target metal to the reaction products is constant. Accordingly, in step S 106c, when the electrical resistance of the surface of each optical film reaches and maintains a constant or invariant value, the coating process is finished and the optical films are produced. In each optical film, a density of the ions of the target metal gradually increases along a direction from the bare surface of the substrate to the exposed surface of the optical film.

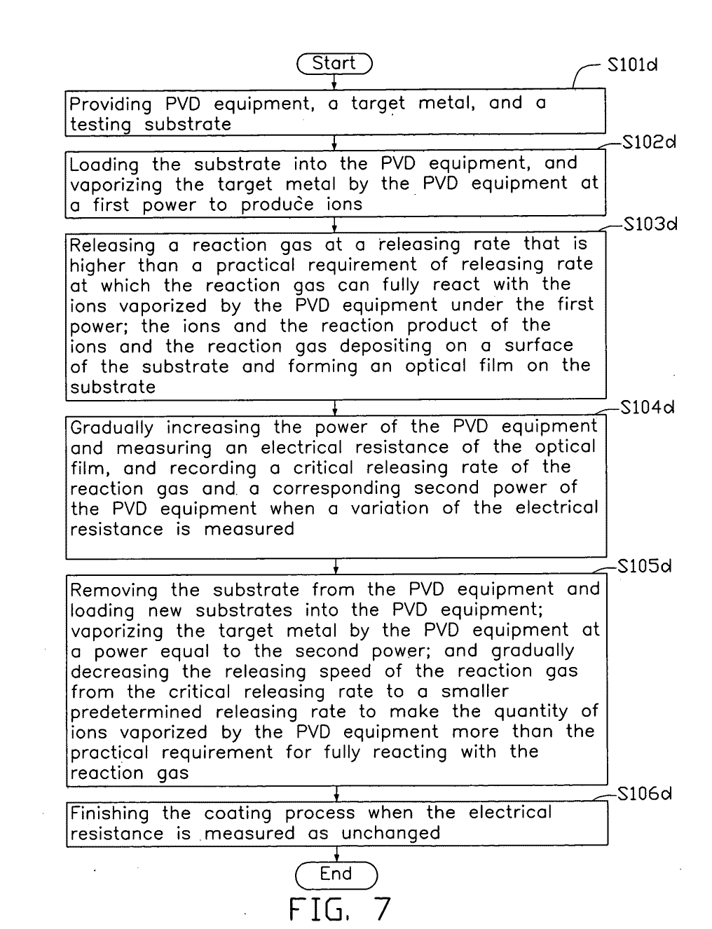

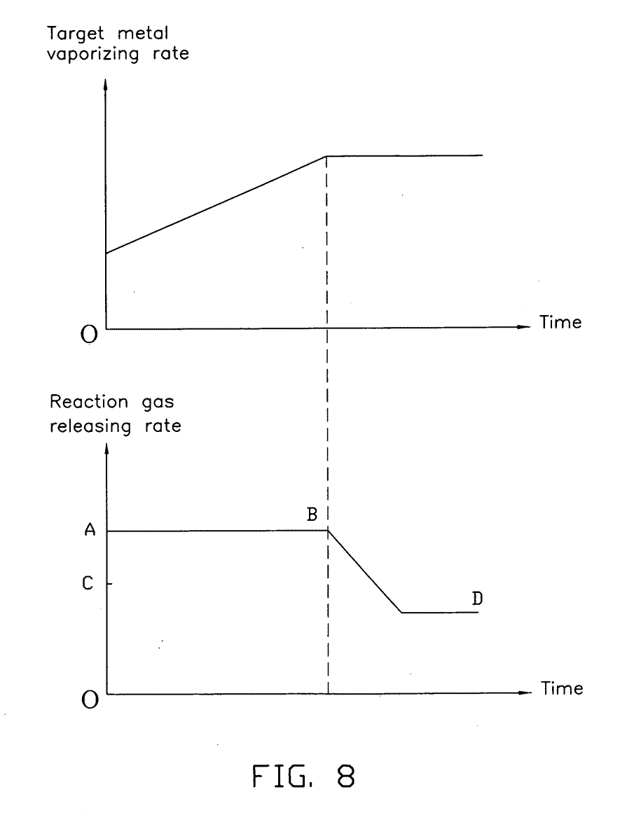

FIGS. 7 and 8 relate to a coating method of a fourth exemplary embodiment. The coating method is similar to that of the first exemplary embodiment, and includes steps as follows. The first and second steps S101d and S102d of the fourth exemplary embodiment are similar to steps S101a and S102a of the first exemplary embodiment. Accordingly, a description of steps S101d and S102d is omitted, for the sake of brevity.

In step S103d, the gas injector releases reaction gas at a first releasing rate A (sccm), which is higher than a practical requirement of a releasing rate at which the reaction gas released by the gas injector can fully react with the ions vaporized from the target metal by the cathode ray gun operating at the first power. In detail, a vaporizing rate of the target metal can be read from the PVD equipment, and a theoretical value C (sccm) of the releasing rate of the reaction gas is directly calculated accordingly. The actual vaporizing rate depends on characteristics (such as melting point) of the target metal and the power of the cathode ray gun of the PVD equipment. In the present embodiment, the actual vaporizing rate depends on characteristics of Cr or Ti, including the melting point of Cr or Ti, and importantly depends on the power of the cathode ray gun of the PVD equipment. In the present embodiment, the reference power of the cathode ray gun of the PVD is proper at approximately 1000 W. At the theoretical value C (sccm) of the releasing rate, the reaction gas released by the gas injector can theoretically fully react with the vaporized ions of the target metal. The theoretical value C (sccm) serves as a reference standard for setting up the first releasing rate A (sccm). In the present embodiment, the first releasing rate A (sccm) is higher than the theoretical value C (sccm). The difference between the first releasing rate A (sccm) and the theoretical value C (sccm) can be of a proportion indicated in FIG. 8, as if the chart therein of releasing rate of reaction gas versus time were drawn to scale. In the present embodiment, the reaction gas released by the gas injector is oxygen or nitrogen, and correspondingly the reaction products produced during the reaction of the reaction gas and the target metal are titanium oxides, chromium oxides, titanium nitrides, or chromium nitrides. During the coating process, all of the vaporized ions are reacted with the reaction gas and deposited on the surface of the testing substrate to form an optical film.

In step S104d, the power of the cathode ray gun of the PVD equipment is gradually increased, and simultaneously an electrical resistance of the surface of the optical film is repeatedly measured. In this process, the vaporized ions can fully react with the reaction gas because the quantity of the reaction gas is more than a practical requirement for fully reacting with the vaporized ions. Therefore, the electrical resistance of the surface of the optical film remains unchanged before the residual reaction gas has been consumed by the vaporized ions of the target metal. With the increasing of the power of the cathode ray gun, the quantity of the vaporized ions increases correspondingly, and therefore, the residual reaction gas can be consumed more and more by the increased presence of vaporized ions. When the quantity of the vaporized ions exceeds the practical requirement for fully reacting with the reaction gas, a portion of the vaporized ions is deposited on the optical film along with the depositing of the reaction products of the reaction gas and the vaporized ions. As a result, the electrical resistance of the optical film changes. When a variation of the electrical resistance of the surface of the optical film is measured, it means that the vaporized ions and the reaction gas are not completely reacted. A second power of the cathode ray gun that is supplied at the time of the variation of the electrical resistance is correspondingly recorded as a reference parameter. In this embodiment, the gas injector releases the reaction gas at a releasing rate equal to the first releasing rate A (sccm) throughout the calibrating process. Thus the critical releasing rate B (sccm) is larger than the theoretical value C (sccm). The time needed for the electrical resistance of the surface of the optical film to reach the constant or invariant value is, for example, of the order of 1 hour. Understandably, the optical parameters of the optical film can vary according different requirements, and can be achieved by increasing the power of the cathode ray gun to change the composition of the optical film.

After the calibrating process, the reference parameter of the second power of the cathode ray gun has been obtained, and the testing substrate is removed from the reaction chamber of the PVD equipment. In step S105d, a plurality of new and clean substrates are loaded into the reaction chamber of the PVD equipment. To form an optical film on each of the substrates includes operating the gas injector to release reaction gas at a releasing rate that gradually decreases from a releasing rate B (sccm) to a releasing rate D (sccm), while operating the cathode ray gun at the second power during this time. Thereby, the vaporizing rate of the target metal at the second power is higher than the practical requirement for fully reacting the vaporized ions of the target metal with the reaction gas released at the releasing rate lower than the releasing rate B (sccm). In this way, an optical film is gradually built on a bare surface of each of the substrates.

In the present embodiment, the releasing rate D (sccm) is lower than the theoretical value C (sccm). When the cathode ray gun stably operates at the second power and the releasing rate remains at the releasing rate D (sccm), the vaporizing quantity of the target metal and the releasing quantity of the reaction gas remain unchanged. Therefore the proportion of the vaporized ions of the target metal to the reaction products is constant. Accordingly, in step S106d, when the electrical resistance of each optical film reaches and maintains a constant or invariant value, the coating process is finished and the optical films are produced. In each optical film, a density of the ions of the target metal gradually increases along a direction from the bare surface of the substrate to the exposed surface of the optical film.

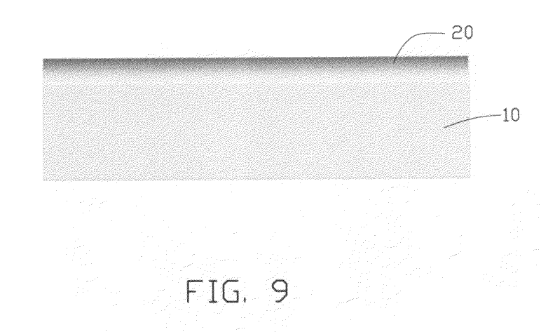

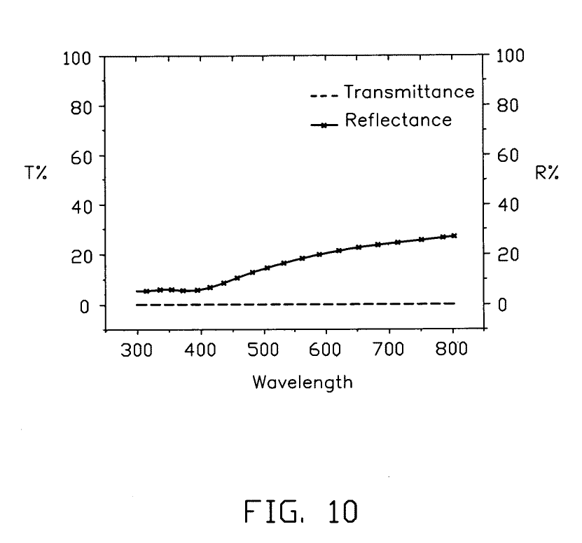

Referring to FIG. 9, a transparent substrate 10 with an optical film 20 formed thereon is shown. The optical film 20 is comprised of pure ions of a target metal and reaction products (or “reaction compounds”) of a reaction gas and the target metal. The optical film 20 is formed by one of the coating methods of the first through fourth embodiments. The optical film 20 is a single layer structure with gradually varying compositional characteristics, but has characteristics similar to those of a multilayer structure optical film. In particular, the proportion of the pure ions to the reaction compounds gradually changes along a predetermined direction. The pure ions in the optical film 20 can reflect light well, and the reaction compounds can absorb light well. According to the present embodiment, portions of the optical film 20 farther away from the transparent substrate 10 have more pure ions than portions closer to the transparent substrate 10, and therefore such farther portions have better light reflection capability. In contrast, portions of the optical film 20 closer to the transparent substrate 10 have more reaction compounds than portions farther away from the transparent substrate 10, and therefore such closer portions have better light absorbing capability. Referring to FIG. 10, the transmittance of the optical film 20 for visible light scarcely changes across the entire visible light spectrum. In the present embodiment, the pure ions of the optical film 20 have been vaporized from the target metal material of chromium (Cr) or titanium (Ti). The reaction compounds in the optical film 20 may be one of titanium oxides, chromium oxides, titanium nitrides, or chromium nitrides.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. An optical film comprising:
a transparent substrate having a surface; and
an optical film coated on the surface of the transparent substrate, the optical film comprising pure ions and reaction compounds mixed with the pure ions, the proportion of the ions to the reaction compounds in the optical film gradually changing along a direction from the surface of the transparent substrate to a surface of the optical film farthest from the surface of the transparent substrate.

2. The optical film of claim 1, wherein the proportion of the ions to the reaction compounds in the optical film gradually increases along the direction from the surface of the transparent substrate to the surface of the optical film farthest from the surface of the transparent substrate.

3. The optical film of claim 1, wherein a density of the ions gradually increases along the direction from the surface of the transparent substrate to the surface of the optical film farthest from the surface of the transparent substrate.

4. The optical film of claim 1, wherein the pure ions are capable of reflecting light beams, and the reaction compounds are capable of absorbing light beams.

5. The optical film of claim 4, wherein the pure ions are metal ions.

6. The optical film of claim 5, wherein the metal ions are one of chromium ions and titanium ions.

7. The optical film of claim 6, wherein the reaction compounds are one type selected from the group consisting of titanium oxides, chromium oxides, titanium nitrides, and chromium nitrides.

8. A coating method comprising:
providing physical vapor deposition (PVD) equipment, a target metal, a testing substrate, and a plurality of workpiece substrates; wherein the PVD equipment comprises a reaction chamber, and a cathode ray gun and a gas injector arranged in the reaction chamber;
executing a calibrating process, comprising:
loading the target metal into the reaction chamber of the PVD equipment;
operating the cathode ray gun at a predetermined power to vaporize a surface of the target metal to produce ions of the target metal and operating the gas injector to release reaction gas into the reaction chamber at a predetermined releasing rate to react with the ions; and
keeping one of the power of the cathode ray gun and the releasing rate of the gas injector constant, and gradually adjusting the other one of the releasing rate and the power to a value at which the ions vaporized from the target metal and the reaction gas react with each other completely; and recording the corresponding power or the releasing rate at which the ions and the reaction gas react with each other completely as a reference parameter; and
executing a workpiece coating process, comprising:
removing the testing substrate from the reaction chamber, and loading the workpiece substrates into the reaction chamber;
keeping said other one of the releasing rate and the power at a value equal to the corresponding reference parameter obtained in the calibrating process, and gradually adjusting said one of the power and the releasing rate to a value at which the quantity of ions produced by the cathode ray gun is more than a quantity needed for reacting the ions with the reaction gas completely, such that a surface of each of the workpiece substrates is coated with a film comprising ions of the target metal and reaction products of reaction of the ions vaporized from the target metal with the reaction gas, wherein the proportion of the ions and the reaction products changes gradually along a direction from a surface of the workpiece substrate to a surface of the film farthest from the surface of the workpiece substrate;
measuring an electrical resistance of at least one of the films being formed; and
finishing the coating process of the workpiece substrates when the electrical resistance of the at least one of the films is measured as not changing.

9. The coating method of claim 8, wherein:
executing the calibrating process comprises:
operating the cathode ray gun at a first power, and gradually increasing the releasing rate of the reaction gas of the gas injector to a critical releasing rate at which the ions vaporized from the target metal react with the released reaction gas completely; and
recording the critical releasing rate as the reference parameter; and
executing the workpiece coating process comprises:
releasing the reaction gas by the gas injector at the critical releasing rate, and operating the cathode ray gun at a second power larger than the first power to make the quantity of the ions produced by the cathode ray gun more than the quantity needed for reacting the ions with the reaction gas completely.

10. The coating method of claim 8, wherein:
executing the calibrating process comprises:
keeping the gas injector releasing reaction gas at a first releasing rate, and gradually increasing the power of the cathode ray gun from a first power to a second power at which the ions vaporized from the target metal react with the released reaction gas completely, and recording the second power as the reference parameter; and
executing the workpiece coating process comprises:
increasing the power of the cathode ray gun to a third power larger than the second power to make the quantity of the ions produced by the cathode ray gun more than the quantity needed for reacting the ions with the reaction gas completely.

11. The coating method of claim 8, wherein:
executing the calibrating process comprises:
operating the cathode ray gun at a first power, and gradually increasing the releasing rate of the reaction gas of the gas injector to a critical releasing rate at which the ions vaporized from the target metal react with the released reaction gas completely, and recording the critical releasing rate as the reference parameter; and
executing the workpiece coating process comprises:
operating the cathode ray gun at the first power; and
releasing the reaction gas by the gas injector at a practical releasing rate lower than the critical releasing rate to make the quantity of the ions produced by the cathode ray gun more than the quantity needed for reacting the ions with the reaction gas completely.

12. The coating method of claim 8, wherein:
executing the calibrating process comprises:
keeping the gas injector releasing reaction gas at a first releasing rate, and gradually increasing the power of the cathode ray gun from a first power to a second power at which the ions vaporized from the target metal react with the released reaction gas completely, and recording the second power as the reference parameter; and
executing the workpiece coating process comprises:
operating the cathode ray gun at the second power; and
releasing the reaction gas by the gas injector at a practical releasing rate lower than the critical releasing rate to make the quantity of the ions produced by the cathode ray gun more than the quantity needed for reacting the ions with the reaction gas completely.
